(19) United States
(12) Patent Application Publication
(10) Pub. No.: US 2024/0255358 A1
(43) Pub. Date: Aug. 1, 2024

(54) METHOD AND ELECTRONIC DEVICE FOR PREDICTING OUTSIDE TEMPERATURE

(71) Applicant: Samsung Electronics Co., Ltd., Suwon-si (KR)

(72) Inventors: Sangmin LEE, Suwon-si (KR); Sungyong BANG, Suwon-si (KR); Sunghun JUNG, Suwon-si (KR); Jongwoo KIM, Suwon-si (KR); Hakryoul KIM, Suwon-si (KR); Mooyoung KIM, Suwon-si (KR)

(21) Appl. No.: 18/584,534

(22) Filed: Feb. 22, 2024

Related U.S. Application Data
(63) Continuation of application No. PCT/KR2024/001362, filed on Jan. 29, 2024.

(30) Foreign Application Priority Data
Jan. 31, 2023 (KR) 10-2023-0013222

(51) Int. Cl. G01K 7/42

(52) U.S. Cl. CPC G01K 7/42

(57) ABSTRACT

According to an embodiment, an electronic device includes: at least one first component and at least one second component arranged in an internal space of the electronic device wherein the first and second components have temperatures that vary differently depending on the operation of the electronic device, a first temperature sensor configured to measure the temperature of the at least one first component, a second temperature sensor configured to measure the temperature of the at least one second component, a memory, and at least one processor operatively connected to the at least one first component, the at least one second component, the first temperature sensor, the second temperature sensor, and the memory, wherein at least one processor is configured to: identify a prediction model related to prediction of the outside temperature stored in the memory, acquire a first temperature of the at least one first component through the first temperature sensor according to a specified period, acquire a second temperature of the at least one second component through the second temperature sensor according to a specified period, and predict the outside temperature corresponding to the acquired first temperature and the acquired second temperature based on the identified prediction model.

### CROSS-REFERENCE TO RELATED APPLICATIONS

This application is a continuation of International Application No. PCT/KR2024/001362 designating the United States, filed on Jan. 29, 2024, in the Korean Intellectual Property Receiving Office, and claiming priority to Korean Patent Application No. 10-2023-0013222, filed on Jan. 31, 2023, in the Korean Intellectual Property Office, the disclosures of each of which are incorporated by reference herein in their entireties.

### BACKGROUND

### Field

The disclosure relates to a method and electronic device for predicting the outside temperature.

### Description of Related Art

Portable electronic devices have evolved to perform various functions, and when these devices perform various functions, processors can consume a large amount of power and generate heat. For example, the heat generated by the processor may cause an increase in the internal temperature of the electronic device. The electronic devices can manage their internal temperature based on the temperature of the external environment, and thus accurate measurement of the outside temperature (e.g., external temperature, ambient temperature) might be necessary. The electronic devices may require various methods of measuring external air in order to accurately measure the outside temperature.

The above information may be provided as background technology for the purpose of aiding understanding of the disclosure. No assertion is made that any of the disclosed content can be applied as prior art related to this disclosure.

The electronic device may have at least one temperature sensor arranged in response to at least one component arranged in the internal space of the electronic device. The electronic device may predict the outside temperature by establishing a correlation between current consumed by the electronic device and temperature data measured through a temperature sensor, but many errors may occur in determining the correlation. For example, the temperature does not increase in proportion to the consumed current, and as time progresses, it may be difficult to accurately predict the outside temperature. For example, because the current consumption does not occur at a constant value and the time at which the current consumption occurs is variable, it may be difficult to establish a correlation between the consumed current and the temperature data.

### SUMMARY

Embodiments of the disclosure provide an electronic device which can measure the temperature corresponding to each of at least one component and measure the outside temperature (e.g., temperature of the external environment, outdoor air temperature) based on a plurality of pieces of measured temperature data. Embodiments of the disclosure provide an electronic device which can accurately predict the outside temperature based on a plurality of pieces of temperature data measured using a plurality of temperature sensors.

In accordance with an example embodiment of the disclosure, an electronic device may include: at least one first component and at least one second component arranged in an internal space of the electronic device wherein temperatures of the first component and second component vary differently depending on an operation of the electronic device; a first temperature sensor configured to measure the temperature of the at least one first component; a second temperature sensor configured to measure the temperature of the at least one second component; a memory; and at least one processor comprising processing circuitry operatively connected to the at least one first component, the at least one second component, the first temperature sensor, the second temperature sensor, and the memory. At least one processor may be configured to identify a prediction model related to prediction of the outside temperature stored in the memory. At least one processor configured to acquire a first temperature of the at least one first component through the first temperature sensor according to a specified period. At least one processor configured to acquire a second temperature of the at least one second component through the second temperature sensor according to the specified period. At least one processor configured to predict the outside temperature corresponding to the acquired first temperature and the acquired second temperature based on the identified prediction model.

In accordance with an example embodiment of the disclosure, an electronic device may be configured to perform: a method of predicting an outside temperature comprising: identifying a prediction model related to prediction of the outside temperature stored in a memory; acquiring a first temperature of at least one first component through a first temperature sensor according to a specified period; acquiring a second temperature of at least one second component through a second temperature sensor according to the specified period; and predicting outside temperatures corresponding to the acquired first temperature and the acquired second temperature based on the identified prediction model. The temperatures of the at least one first component and the at least one second component may vary differently depending on the operation of the electronic device.

According to an example embodiment, a non-transitory computer-readable storage medium (or a computer program product) storing one or more programs may be provided. According to an example embodiment, the one or more programs may include instructions which, when executed by at least one processor of an electronic device, cause the electronic device to perform operations comprising: identifying a prediction model related to prediction of outside temperature stored in a memory; acquiring a first temperature of at least one first component through a first temperature sensor according to a specified period; acquiring a second temperature of at least one second component through a second temperature sensor according to the specified period; and predicting outside temperatures corresponding to the acquired first temperature and the acquired second temperature based on the identified prediction model. According to an example embodiment, the temperatures of the at least one first component and the at least one second component may vary differently depending on the operation of the electronic device.

According to an example embodiment, the electronic device may measure the temperature in response to each of at least one component (e.g., application processor {AP}, battery, charger, universal serial bus {USB}, Wi-Fi module, camera flash, and/or modem) arranged in an internal space of the electronic device. The electronic device may calculate/determine a temperature difference between various components based on a plurality of measured temperature values and predict the outside temperature based on the temperature difference.

According to an example embodiment, the electronic device may reflect the plurality of measured temperature values in a specified equation and predict the outside temperature based on the equation. According to an example embodiment, the electronic device may predict the outside temperature relatively more accurately. In an example embodiment, accuracy according to the prediction of the outside temperature may be improved. In an example embodiment, functions and operations that utilize the outside temperature may be performed more accurately.

The effects that can be obtained from the disclosure are not limited to the effects mentioned above, and other effects not mentioned above will be clearly understood by those skilled in the art from the description below.

### BRIEF DESCRIPTION OF THE DRAWINGS

In relation to the description of the drawings, the same or similar reference signs may be used for the same or similar components. Further, the above and other aspects, features and advantages of certain embodiments of the present disclosure will be more apparent from the following detailed description, taken in conjunction with the accompanying drawings, in which:

FIG. 1 is a block diagram illustrating an example electronic device in a network environment according to various embodiments;

FIG. 2 is a diagram illustrating an example process for predicting the outside temperature according to various embodiments;

FIG. 3 is a block diagram illustrating an example configuration of an electronic device according to various embodiments;

FIG. 4 is a flowchart illustrating an example method of implementing a prediction model according to various embodiments; and

FIG. 5 is a flowchart illustrating an example method of predicting the outdoor temperature according to various embodiments.

### DETAILED DESCRIPTION

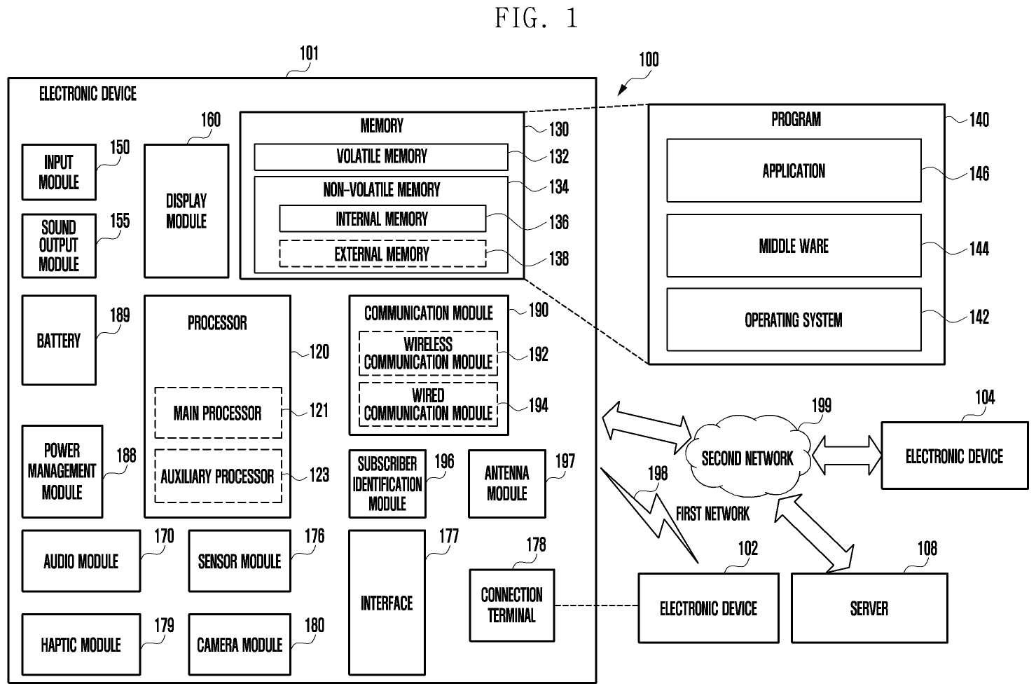

FIG. 1 is a block diagram illustrating an example electronic device 101 in a network environment 100 according to various embodiments. Referring to FIG. 1, the electronic device 101 in the network environment 100 may communicate with an electronic device 102 via a first network 198 (e.g., a short-range wireless communication network), or at least one of an electronic device 104 or a server 108 via a second network 199 (e.g., a long-range wireless communication network). According to an embodiment, the electronic device 101 may communicate with the electronic device 104 via the server 108. According to an embodiment, the electronic device 101 may include a processor 120, memory 130, an input module 150, a sound output module 155, a display module 160, an audio module 170, a sensor module 176, an interface 177, a connecting terminal 178, a haptic module 179, a camera module 180, a power management module 188, a battery 189, a communication module 190, a subscriber identification module (SIM) 196, or an antenna module 197. In various embodiments, at least one of the components (e.g., the connecting terminal 178) may be omitted from the electronic device 101, or one or more other components may be added in the electronic device 101. In various embodiments, some of the components (e.g., the sensor module 176, the camera module 180, or the antenna module 197) may be implemented as a single component (e.g., the display module 160).

The processor 120 may include various processing circuitry. For example, as used herein, including the claims, the term “processor” may include various processing circuitry, including at least one processor, wherein one or more processors of at least one processor may be configured to perform the various functions described herein. Additionally, the at least one processor may include a combination of processors performing various of the recited/disclosed functions. The processor 120 may execute, for example, software (e.g., a program 140) to control at least one other component (e.g., a hardware or software component) of the electronic device 101 coupled with the processor 120, and may perform various data processing or computation. According to an embodiment, as at least part of the data processing or computation, the processor 120 may store a command or data received from another component (e.g., the sensor module 176 or the communication module 190) in volatile memory 132, process the command or the data stored in the volatile memory 132, and store resulting data in non-volatile memory 134. According to an embodiment, the processor 120 may include a main processor 121 (e.g., a central processing unit (CPU) or an application processor (AP)), or an auxiliary processor 123 (e.g., a graphics processing unit (GPU), a neural processing unit (NPU), an image signal processor (ISP), a sensor hub processor, or a communication processor (CP)) that is operable independently from, or in conjunction with, the main processor 121. For example, when the electronic device 101 includes the main processor 121 and the auxiliary processor 123, the auxiliary processor 123 may be adapted to consume less power than the main processor 121, or to be specific to a specified function. The auxiliary processor 123 may be implemented as separate from, or as part of the main processor 121.

The auxiliary processor 123 may control at least some of functions or states related to at least one component (e.g., the display module 160, the sensor module 176, or the communication module 190) among the components of the electronic device 101, instead of the main processor 121 while the main processor 121 is in an inactive (e.g., sleep) state, or together with the main processor 121 while the main processor 121 is in an active state (e.g., executing an application). According to an embodiment, the auxiliary processor 123 (e.g., an image signal processor or a communication processor) may be implemented as part of another component (e.g., the camera module 180 or the communication module 190) functionally related to the auxiliary processor 123. According to an embodiment, the auxiliary processor 123 (e.g., the neural processing unit) may include a hardware structure specified for artificial intelligence model processing. An artificial intelligence model may be generated by machine learning. Such learning may be performed, e.g., by the electronic device 101 where the artificial intelligence is performed or via a separate server (e.g., the server 108). Learning algorithms may include, but are not limited to, e.g., supervised learning, unsupervised learning, semi-supervised learning, or reinforcement learning. The artificial intelligence model may include a plurality of artificial neural network layers. The artificial neural network may be a deep neural network (DNN), a convolutional neural network (CNN), a recurrent neural network (RNN), a restricted boltzmann machine (RBM), a deep belief network (DBN), a bidirectional recurrent deep neural network (BRDNN), deep Q-network or a combination of two or more thereof but is not limited thereto. The artificial intelligence model may, additionally or alternatively, include a software structure other than the hardware structure.

The memory 130 may store various data used by at least one component (e.g., the processor 120 or the sensor module 176) of the electronic device 101. The various data may include, for example, software (e.g., the program 140) and input data or output data for a command related thereto. The memory 130 may include the volatile memory 132 or the non-volatile memory 134.

The program 140 may be stored in the memory 130 as software, and may include, for example, an operating system (OS) 142, middleware 144, or an application 146.

The input module 150 may receive a command or data to be used by another component (e.g., the processor 120) of the electronic device 101, from the outside (e.g., a user) of the electronic device 101. The input module 150 may include, for example, a microphone, a mouse, a keyboard, a key (e.g., a button), or a digital pen (e.g., a stylus pen).

The sound output module 155 may output sound signals to the outside of the electronic device 101. The sound output module 155 may include, for example, a speaker or a receiver. The speaker may be used for general purposes, such as playing multimedia or playing record. The receiver may be used for receiving incoming calls. According to an embodiment, the receiver may be implemented as separate from, or as part of the speaker.

The display module 160 may visually provide information to the outside (e.g., a user) of the electronic device 101. The display module 160 may include, for example, a display, a hologram device, or a projector and control circuitry to control a corresponding one of the display, hologram device, and projector. According to an embodiment, the display module 160 may include a touch sensor adapted to detect a touch, or a pressure sensor adapted to measure the intensity of force incurred by the touch.

The audio module 170 may convert a sound into an electrical signal and vice versa. According to an embodiment, the audio module 170 may obtain the sound via the input module 150, or output the sound via the sound output module 155 or a headphone of an external electronic device (e.g., an electronic device 102) directly (e.g., wiredly) or wirelessly coupled with the electronic device 101.

The sensor module 176 may detect an operational state (e.g., power or temperature) of the electronic device 101 or an environmental state (e.g., a state of a user) external to the electronic device 101, and then generate an electrical signal or data value corresponding to the detected state. According to an embodiment, the sensor module 176 may include, for example, a gesture sensor, a gyro sensor, an atmospheric pressure sensor, a magnetic sensor, an acceleration sensor, a grip sensor, a proximity sensor, a color sensor, an infrared (IR) sensor, a biometric sensor, a temperature sensor, a humidity sensor, or an illuminance sensor.

The interface 177 may support one or more specified protocols to be used for the electronic device 101 to be coupled with the external electronic device (e.g., the electronic device 102) directly (e.g., wiredly) or wirelessly. According to an embodiment, the interface 177 may include, for example, a high definition multimedia interface (HDMI), a universal serial bus (USB) interface, a secure digital (SD) card interface, or an audio interface.

A connecting terminal 178 may include a connector via which the electronic device 101 may be physically connected with the external electronic device (e.g., the electronic device 102). According to an embodiment, the connecting terminal 178 may include, for example, a HDMI connector, a USB connector, a SD card connector, or an audio connector (e.g., a headphone connector).

The haptic module 179 may convert an electrical signal into a mechanical stimulus (e.g., a vibration or a movement) or electrical stimulus which may be recognized by a user via his tactile sensation or kinesthetic sensation. According to an embodiment, the haptic module 179 may include, for example, a motor, a piezoelectric element, or an electric stimulator.

The camera module 180 may capture a still image or moving images. According to an embodiment, the camera module 180 may include one or more lenses, image sensors, image signal processors, or flashes.

The power management module 188 may manage power supplied to the electronic device 101. According to an embodiment, the power management module 188 may be implemented as at least part of, for example, a power management integrated circuit (PMIC).

The battery 189 may supply power to at least one component of the electronic device 101. According to an embodiment, the battery 189 may include, for example, a primary cell which is not rechargeable, a secondary cell which is rechargeable, or a fuel cell.

The communication module 190 may support establishing a direct (e.g., wired) communication channel or a wireless communication channel between the electronic device 101 and the external electronic device (e.g., the electronic device 102, the electronic device 104, or the server 108) and performing communication via the established communication channel. The communication module 190 may include one or more communication processors that are operable independently from the processor 120 (e.g., the application processor (AP)) and supports a direct (e.g., wired) communication or a wireless communication. According to an embodiment, the communication module 190 may include a wireless communication module 192 (e.g., a cellular communication module, a short-range wireless communication module, or a global navigation satellite system (GNSS) communication module) or a wired communication module 194 (e.g., a local area network (LAN) communication module or a power line communication (PLC) module). A corresponding one of these communication modules may communicate with the external electronic device via the first network 198 (e.g., a short-range communication network, such as Bluetooth™, wireless-fidelity (Wi-Fi) direct, or infrared data association (IrDA)) or the second network 199 (e.g., a long-range communication network, such as a legacy cellular network, a 5G network, a next-generation communication network, the Internet, or a computer network (e.g., LAN or wide area network (WAN)). These various types of communication modules may be implemented as a single component (e.g., a single chip), or may be implemented as multi components (e.g., multi chips) separate from each other. The wireless communication module 192 may identify and authenticate the electronic device 101 in a communication network, such as the first network 198 or the second network 199, using subscriber information (e.g., international mobile subscriber identity (IMSI)) stored in the subscriber identification module 196.

The wireless communication module 192 may support a 5G network, after a 4G network, and next-generation communication technology, e.g., new radio (NR) access technology. The NR access technology may support enhanced mobile broadband (cMBB), massive machine type communications (mMTC), or ultra-reliable and low-latency communications (URLLC). The wireless communication module 192 may support a high-frequency band (e.g., the mmWave band) to achieve, e.g., a high data transmission rate. The wireless communication module 192 may support various technologies for securing performance on a high-frequency band, such as, e.g., beamforming, massive multiple-input and multiple-output (massive MIMO), full dimensional MIMO (FD-MIMO), array antenna, analog beam-forming, or large scale antenna. The wireless communication module 192 may support various requirements specified in the electronic device 101, an external electronic device (e.g., the electronic device 104), or a network system (e.g., the second network 199). According to an embodiment, the wireless communication module 192 may support a peak data rate (e.g., 20 Gbps or more) for implementing eMBB, loss coverage (e.g., 164 dB or less) for implementing mMTC, or U-plane latency (e.g., 0.5 ms or less for each of downlink (DL) and uplink (UL), or a round trip of 1 ms or less) for implementing URLLC.

The antenna module 197 may transmit or receive a signal or power to or from the outside (e.g., the external electronic device) of the electronic device 101. According to an embodiment, the antenna module 197 may include an antenna including a radiating element including a conductive material or a conductive pattern formed in or on a substrate (e.g., a printed circuit board (PCB)). According to an embodiment, the antenna module 197 may include a plurality of antennas (e.g., array antennas). In such a case, at least one antenna appropriate for a communication scheme used in the communication network, such as the first network 198 or the second network 199, may be selected, for example, by the communication module 190 (e.g., the wireless communication module 192) from the plurality of antennas. The signal or the power may then be transmitted or received between the communication module 190 and the external electronic device via the selected at least one antenna. According to an embodiment, another component (e.g., a radio frequency integrated circuit (RFIC)) other than the radiating element may be additionally formed as part of the antenna module 197.

According to various embodiments, the antenna module 197 may form a mmWave antenna module. According to an embodiment, the mmWave antenna module may include a printed circuit board, a RFIC disposed on a first surface (e.g., the bottom surface) of the printed circuit board, or adjacent to the first surface and capable of supporting a designated high-frequency band (e.g., the mmWave band), and a plurality of antennas (e.g., array antennas) disposed on a second surface (e.g., the top or a side surface) of the printed circuit board, or adjacent to the second surface and capable of transmitting or receiving signals of the designated high-frequency band. For example, the plurality of antennas may include a patch array antenna and/or a dipole array antenna.

At least some of the above-described components may be coupled mutually and communicate signals (e.g., commands or data) therebetween via an inter-peripheral communication scheme (e.g., a bus, general purpose input and output (GPIO), serial peripheral interface (SPI), or mobile industry processor interface (MIPI)).

According to an embodiment, commands or data may be transmitted or received between the electronic device 101 and the external electronic device 104 via the server 108 coupled with the second network 199. Each of the electronic devices 102 or 104 may be a device of a same type as, or a different type, from the electronic device 101. According to an embodiment, all or some of operations to be executed at the electronic device 101 may be executed at one or more of the external electronic devices 102, 104, or 108. For example, if the electronic device 101 should perform a function or a service automatically, or in response to a request from a user or another device, the electronic device 101, instead of, or in addition to, executing the function or the service, may request the one or more external electronic devices to perform at least part of the function or the service. The one or more external electronic devices receiving the request may perform the at least part of the function or the service requested, or an additional function or an additional service related to the request, and transfer an outcome of the performing to the electronic device 101. The electronic device 101 may provide the outcome, with or without further processing of the outcome, as at least part of a reply to the request. To that end, a cloud computing, distributed computing, mobile edge computing (MEC), or client-server computing technology may be used, for example. The electronic device 101 may provide ultra low-latency services using, e.g., distributed computing or mobile edge computing. In an embodiment, the external electronic device 104 may include an internet-of-things (IoT) device. The server 108 may be an intelligent server using machine learning and/or a neural network. According to an embodiment, the external electronic device 104 or the server 108 may be included in the second network 199. The electronic device 101 may be applied to intelligent services (e.g., smart home, smart city, smart car, or healthcare) based on 5G communication technology or IoT-related technology.

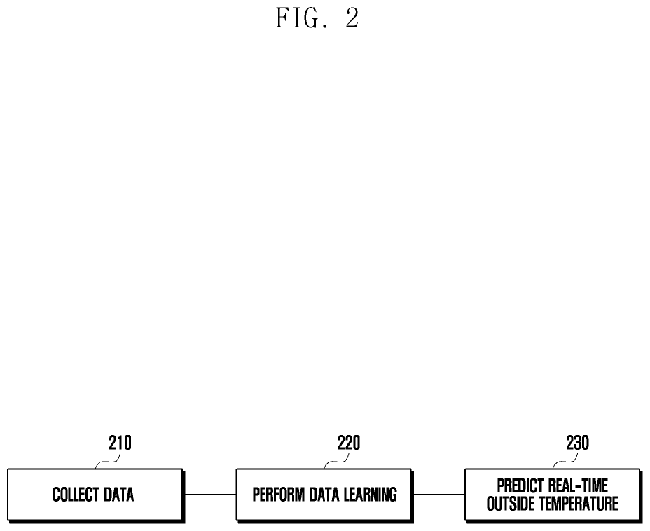

FIG. 2 is a diagram illustrating an example process for predicting the outside temperature according to various embodiments.

An electronic device of FIG. 2 may be at least partially similar to the electronic device 101 of FIG. 1 or may further include various embodiments of the electronic device 101. According to an embodiment, the electronic device 101 may have a plurality of components arranged therein, and may use a temperature sensor to measure the temperature corresponding to each of the components. According to an embodiment, at least one temperature sensor may be arranged in response to at least one component, and may accurately measure the temperature of the at least one component.

Referring to FIG. 2, in operation 210, the electronic device 101 may collect data (e.g., temperature-related data) to determine a temperature correlation between the ambient temperature and at least one component. For example, the electronic device 101 may conduct various experiments (e.g., tests) and acquire and store temperature-related data. According to an embodiment, within a space configured to a certain temperature (e.g., a temperature between about 20 degrees and about 45 degrees, an external temperature based on the environment in which the electronic device 101 is used), the electronic device 101 may perform various functions and operations, and measure the temperature (e.g., temperature-related data) corresponding to each of the at least one component according to the performance of the functions and operations.

According to an embodiment, an example in which the electronic device 101 is utilized in various ways may be configured, and the functions and operations of the electronic device 101 may be performed based on the configured scenario. For example, a first example may include a scenario in which a camera recording function is performed to measure the temperature of a camera module (e.g., the camera module 180 in FIG. 1). A second example may include a scenario in which a game application is driven for a certain period of time to identify a heat generation condition according to the load of a graphics processing unit (GPU). A third example may include a scenario in which the CPU is overloaded due to the performance of various functions and operations. According to an embodiment, the electronic device 101 may determine a correlation between a predetermined (e.g., specified) outside temperature and temperature data corresponding to the at least one component based on various configured scenarios (e.g., first scenario, second scenario, and third scenario). According to an embodiment, the configured scenario may not be limited to the operation of a specific component. The configured scenario may include a scenario in which a plurality of components operate substantially simultaneously or sequentially. The electronic device 101 may store temperature-related data (e.g., temperature-related information) based on the correlation in a memory (e.g., memory 130 in FIG. 1) and predict the outside temperature using the temperature-related data.

Table 1 below illustrates first temperature-related data from an experiment.

TABLE 1

| Outside | | | AP | BAT | USB |
|---|---|---|---|---|---|
| temper- | | Time | temper- | temper- | temper- |
| ature | Scenario | (s) | ature | ature | ature |
| about 20 | Camera | 0 | 20 | 20 | 20 |
| degrees | recording | 10 | 20 | 20 | 20 |
| | | 20 | 21 | 20 | 20 |
| | | 30 | 25 | 21 | 20 |
| | | 40 | 30 | 21 | 21 |

Referring to Table 1, in a state in which the experiment space is configured at about 20 degrees, the electronic device 101 may be performing a camera recording function. For example, when the camera recording function is performed for about 10 seconds, an AP (E.G., application processor) temperature, a BAT (e.g., battery) temperature, and a USB (e.g. USB connection terminal) temperature may be measured at approximately 20 degrees. When the camera recording function is performed for about 30 seconds, about 25 degrees may be measured for the AP temperature, about 21 degrees may be measured for the BAT temperature, and about 20 degrees may be measured for the USB temperature. According to an embodiment, the electronic device 101 may measure the temperature corresponding to the at least one component (e.g., AP, BAT, and USB) based on a configured scenario (e.g., the configured outside temperature is about 20 degrees and the camera recording function is performed), and store the measured temperature value in the memory 130 as the temperature-related data.

In the example of Table 1, it is shown that the temperature of AP, BAT, and USB is measured, but it is not limited to this. According to an embodiment, based on the at least one component (e.g., without limitation, application processor (AP), battery, charger, universal serial bus (USB), Wi-Fi module, camera flash, modem, or the like) arranged in the internal space, the temperature according to the experiment may be measured.

Table 2 below illustrates second temperature-related data through experiment.

TABLE 2

| Outside | | | AP | BAT | USB |
|---|---|---|---|---|---|
| temper- | | Time | temper- | temper- | temper- |
| ature | Scenario | (s) | ature | ature | ature |
| about 30 | Camera | 0 | 30 | 30 | 30 |
| degrees | recording | 10 | 30 | 30 | 30 |
| | | 20 | 31 | 31 | 30 |
| | | 30 | 35 | 32 | 30 |
| | | 40 | 40 | 33 | 31 |

Referring to Table 2, in a state in which the experiment space is configured at about 30 degrees, the electronic device 101 may be performing a camera recording function. According to an embodiment, the electronic device 101 may measure the temperature corresponding to the at least one component (e.g., AP, BAT, and USB) based on a configured scenario (e.g., the configured outside temperature is about 30 degrees and the camera recording function is performed), and store the measured temperature value in the memory 130 as the temperature-related data. According to an embodiment, the electronic device 101 may acquire the temperature-related data corresponding to the at least one component based on various scenarios (e.g., the outside temperature configured to specific temperature, execution of specific function and operation).

According to an embodiment, the at least one component may be classified as a first component (e.g., AP) whose temperature varies relatively sensitively and a second component (e.g., BAT or USB) whose temperature varies relatively insensitively, depending on the performance of the function and operation of the electronic device 101. For example, as the function and operation of the electronic device 101 are performed, the component that is most sensitive to a temperature change may be the AP (e.g., application processor). For example, the first component may include an AP and may include components arranged relatively adjacent to the AP. For example, the second component may include a component that is at least partially exposed to the external environment and is substantially affected by the external temperature. According to an embodiment, in response to the performance of the function and operation of the electronic device 101, the first component may be measured to have a temperature change range that is relatively larger than that of the second component. In response to the performance of the function and operation of the electronic device 101, the second component may be measured to have a temperature change range that is relatively smaller than that of the first component. According to an embodiment, the first component may be prioritized based on sensitivity to the temperature changes, and the second component may be prioritized based on insensitivity to the temperature changes. According to an embodiment, the first component and the second component may be replaced based on priority. For example, when an error occurs in measuring the temperature of a 1-1^{st} component configured to the first priority, the electronic device 101 may utilize the temperature data of a 1-2^{nd} component configured to the second priority.

Referring to Table 1 and Table 2, the AP is configured as the first component, and the BAT and USB are configured as the second component, but the disclosure is not limited thereto. According to an embodiment, the AP included in the first component may have a relatively large amount of temperature change depending on the function and operation of the electronic device 101, and the BAT and USB included in the second component may have a relatively small amount of temperature change.

In operation 210, the electronic device 101 may measure temperature-related data corresponding to the at least one component based on the configured scenario and store the measured temperature-related data in the memory 130. According to an embodiment, when predicting the outside temperature, the electronic device 101 may use artificial intelligence techniques (e.g., machine learning, deep learning) based on the temperature-related data stored in the memory 130. For example, the electronic device 101 may analyze the temperature-related data (e.g., big data) according to the configured scenario and predict the outside temperature by learning the analyzed results.

Referring to FIG. 2, in operation 220, the electronic device 101 may perform data learning using data (e.g., the temperature-related data) collected in operation 210. For example, the electronic device 101 may perform data learning to implement a prediction model for predicting the outside temperature. The electronic device 101 may implement the prediction model for accurately predicting the outside temperature by performing data learning based on the collected data.

Equation 1 below may be configured to predict the outside temperature. The electronic device 101 may perform data learning in operation 220 using Equation 1.

$${T}_{amb - esti} = α * {T}_{USB} + β * MA ( {T}_{AP} - {T}_{BAT} ) + γ * MA ( {T}_{AP} - {T}_{USB} ) + δ \qquad [ Equation 1 ]$$

Equation 1 may include an Equation obtained using AP temperature (e.g., T_{AP}), BAT temperature (e.g., T_{BAT}), USB temperature (e.g., T_{USB}), MA (T_{AP}−T_{BAT}) (e.g., average value of temperature difference values between AP and USB), α, β, γ, δ (e.g., prediction parameter data), and outside temperature (e.g., T_{amb-esti}). According to an embodiment, the electronic device 101 may identify the prediction parameter data (e.g., α, β, γ, and δ data) based on the data (e.g., AP temperature, BAT temperature, USB temperature, and temperature of a configured experimental space {e.g., outdoor temperature}) collected in operation 210, and implement a prediction model (e.g., Equation 1) including the prediction parameter data. For example, the electronic device 101 may combine the data collected in operation 210, reflect the combined data in Equation 1, and determine the prediction parameter data using, for example, and without limitation, an artificial intelligence (AI) technique (e.g., machine learning). The predicted parameter data may be determined as data with minimized/reduced errors when predicting the outdoor temperature. For example, the value α included in the prediction parameter data may include a weight value for the USB temperature. The value β included in the prediction parameter data may include a weight value for a difference between the AP temperature and the BAT temperature, and the value γ may include a weight value for a difference between the AP temperature and the USB temperature. The value δ may include an auxiliary value that are additionally reflected in predicting the outside temperature. Referring to Equation 1, the AP temperature (e.g., T_{AP}) may refer to the temperature of the first component, and the BAT temperature (e.g. T_{BAT}) and/or USB temperature (e.g. T_{USB}) may refer to the temperature of the second component.

According to an embodiment, the electronic device 101 may identify temperature data (e.g., temperature data of the first component, temperature data of the second component) of the components (e.g., AP, BAT, USB) mounted therein. The identified temperature data may be input into a prediction model (e.g., Equation 1 in which the prediction parameter data is reflected) to predict the outside temperature (e.g., T_{amb-esti}).

According to an embodiment, “AP temperature” in Equation 1 may not be limited to the temperature data of the AP. For example, “AP” may be replaced with at least one first component that has a relatively large amount of temperature change due to the execution of the function and operation of the electronic device 101. According to an embodiment, “BAT temperature and USB temperature” in Equation 1 may not be limited to BAT temperature data and USB temperature data. For example, “BAT” and “USB” may be replaced with at least one second component that has a relatively small amount of temperature change (that is relatively greatly affected by the outside temperature) due to the execution of the function and operation of the electronic device 101.

According to an embodiment, the first component may include a component whose temperature varies relatively sensitively depending on the performance of the function and operation of the electronic device 101. For example, the first component may include a component that is relatively less affected by the outside temperature. The first component may include a plurality of components, and the higher the sensitivity to temperature changes, the higher the priority may be configured. In an embodiment, the second component may include a component whose temperature varies relatively insensitively depending on the performance of the function and operation of the electronic device 101. For example, the second component may include a component that is relatively greatly affected by the outside temperature. The second component may include a plurality of components, and the lower the sensitivity to temperature changes, the lower the priority may be configured.

In operation 230, the electronic device 101 may predict the outside temperature in real-time based on the prediction model implemented in operation 220. For example, the processor 120 of the electronic device 101 may measure the temperature of the first component and the temperature of the second component according to a configured time interval (e.g., period), and reflect the measured temperature of the first component and the measured temperature of the second component in the prediction model. The processor 120 may predict the outside temperature at regular periods based on the prediction model.

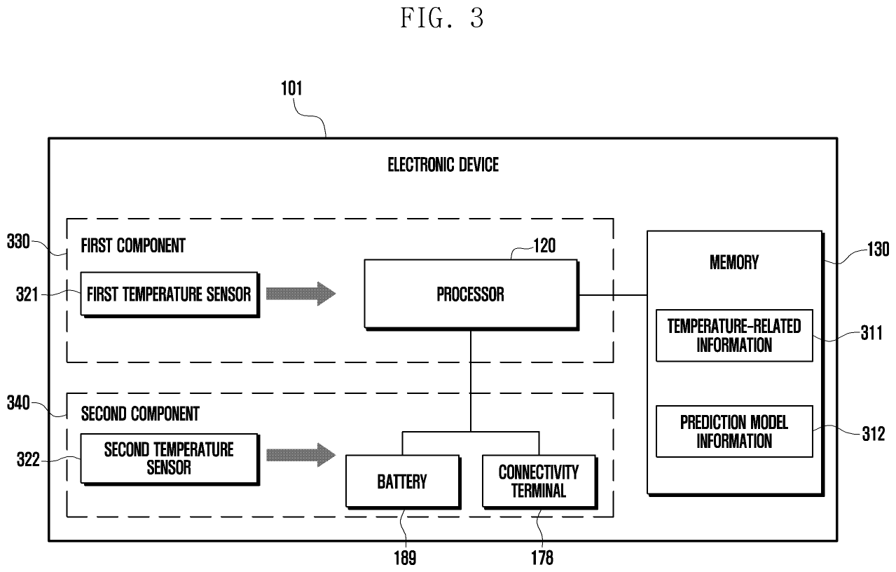

FIG. 3 is a block diagram illustrating an example configuration of an electronic device according to various embodiments.

The electronic device 101 of FIG. 3 may be at least partially similar to the electronic device 101 of FIG. 1 or may further include various embodiments of the electronic device 101. According to an embodiment, the electronic device 101 may have a plurality of components arranged therein, and may use a temperature sensor to measure the temperature corresponding to each of the components. According to an embodiment, at least one temperature sensor may be arranged in response to the at least one component, and may accurately measure the temperature of the at least one component.

Referring to FIG. 3, an electronic device (e.g., the electronic device 101 of FIG. 1) may include a processor (e.g., including processing circuitry) (e.g., the processor 120 of FIG. 1), a memory (e.g., the memory 130 of FIG. 1), a first temperature sensor 321 (e.g., a temperature sensor included in the sensor module 176 of FIG. 1), a second temperature sensor 322 (e.g., a temperature sensor included in the sensor module 176 of FIG. 1), a battery (e.g., the battery 189 of FIG. 1), and a connectivity terminal (e.g., the connectivity terminal 178 of FIG. 1). Temperature-related information 311 and prediction model information 312 may be stored in the memory 130. According to an embodiment, the processor 120 may use a first temperature sensor 321 and a second temperature sensor 322 to measure the temperature corresponding to each of the at least one component arranged therein. For example, the processor 120 may measure a first temperature of a component (e.g., the processor 120) included in a first component 330 using the first temperature sensor 321, and measure a second temperature of a component (e.g., the battery 189 or the connectivity terminal 178) included in a second component 340 using the second temperature sensor 322. The processor 120 may compare or analyze the measured temperature (e.g., the first temperature or the second temperature) and the temperature-related information 311 stored in the memory 130, and reflect the measured temperature in the prediction model information 312, thereby predicting the outside temperature.

According to an embodiment, the processor 120 of the electronic device 101 may include various processing circuitry. For example, as used herein, including the claims, the term “processor” may include various processing circuitry, including at least one processor, wherein one or more processors of at least one processor may be configured to perform the various functions described herein. Additionally, the at least one processor may include a combination of processors performing various of the recited/disclosed functions. The processor 120 may execute a program stored in the memory 130 (e.g., the program 140 in FIG. 1) to control other components (e.g., hardware and/or software components) of the electronic device 101 and/or the external electronic devices (e.g., the electronic devices 102 and 104 of FIG. 1), and perform various data processing and/or calculations. According to an embodiment, the processor 120 may use the first temperature sensor 321 and the second temperature sensor 322 arranged to correspond to the at least one component to acquire temperature data for the at least one component. The processor 120 may predict the outside temperature based on the acquired temperature data. According to an embodiment, the processor 120 may be classified as the first component 330. According to an embodiment, the processor 120 may be operatively, functionally, and/or electrically connected to the memory 130, the first temperature sensor 321, the second temperature sensor 322, the battery 189, and/or the connectivity terminal 178.

According to an embodiment, the temperature-related information 311 and the prediction model information 312 may be stored in the memory 130. According to an embodiment, in a state in which various scenarios are configured, the function and operation of the electronic device 101 may be performed according to each scenario. For example, in a state in which the outside temperature (e.g., the temperature of the experimental space) is configured to a constant value, the processor 120 may use a camera module (e.g., the camera module 180 of FIG. 1) to perform a video recording function or a game-related application, thereby performing a game execution operation. The processor 120 may measure the temperature of the at least one component in a situation where the function and operation are performed according to a configured scenario. Based on the configured scenario, the processor 120 may store, in the memory 130, the temperature-related information 311 that shows a correlation between the outside temperature (e.g., the temperature of the experimental space) and the measured temperature.

According to an embodiment, in a case where the electronic device 101 operates in accordance with the configured scenario, when the temperature of the at least one component is measured as a first value, the processor 120 may predict the outside temperature corresponding to the first value based on the temperature-related information 311. For example, when the electronic device 101 conducts an experiment or test in accordance with a configured scenario (e.g., a scenario in which the temperature of the experiment space is fixed and a specific function and specific operation are performed), the temperature-related information 311 may include temperature data for the at least one component (e.g., the first component 330 and the second component 340) arranged in the electronic device 101.

According to an embodiment, the processor 120 may reflect the temperature-related information 311 in a predetermined mathematical model, and determine prediction parameter data (e.g., the prediction parameter data α, β, γ, and δ of Equation 1) included in the mathematical model. The processor 120 may reflect, in the mathematical model, the prediction parameter data determined based on the temperature-related information 311, and store the mathematical model in which the prediction parameter data is reflected as the prediction model information 312. The processor 120 may store the prediction model information 312 in the memory 130.

According to an embodiment, the processor 120 may measure the temperature for the at least one component (e.g., the first component 330 and the second component 340) according to a predetermined time interval, and reflect the measured temperature in the prediction model information 312, thereby predicting the outside temperature. For example, the processor 120 may acquire a first temperature of the first component 330 through the first temperature sensor 321, and acquire a second temperature of the second component 340 through the second temperature sensor 322. The processor 120 may reflect the first temperature and the second temperature in the prediction model information 312, and predict the outside temperature corresponding to the first temperature and the second temperature.

According to an embodiment, the first component 330 and the second component 340 may include a plurality of components, and may include a temperature sensor associated with each component. For example, the first component 330 may be associated with the first temperature sensor 321 and the second component 340 may be associated with the second temperature sensor 322. For example, a plurality of first temperature sensors 321 may be implemented and may individually measure the temperature of each component included in the first component 330. For example, a plurality of second temperature sensor 322 may be implemented and individually measure the temperature of each component included in the second component 340. According to an embodiment, the processor 120 may activate at least one of the first temperature sensor 321 and the second temperature sensor 322 according to a predetermined time interval, and acquire temperature data corresponding to the at least one component (e.g., the first component 330 and the second component 340) using the activated temperature sensor.

According to an embodiment, the battery 189 may be classified as a component (e.g., the second component 340) that is at least partially arranged in the internal space of the electronic device 101 and relatively greatly affected by the outside temperature. For example, the battery 189 may be a component that is relatively less affected by the heat generated inside the electronic device 101. According to an embodiment, the processor 120 may use the second temperature sensor 322 to measure the temperature of the battery 189.

According to an embodiment, the connectivity terminal 178 may include a connector (e.g., HDMI connector, USB connector, SD card connector, or audio connector {e.g., headphone connector}) physically connected to the external electronic devices (e.g., the electronic devices 102 and 104 of FIG. 1). For example, the connectivity terminal 178 may be arranged to be at least partially exposed to the external environment and classified as a component (e.g., the second component 340) that is relatively greatly affected by the outside temperature. According to an embodiment, the processor 120 may measure the temperature of the connectivity terminal 178 using the second temperature sensor 322.

According to an embodiment, the processor 120 itself may be classified as a component (e.g., the first component 330) that generates a lot of heat when the function and operation of the electronic device 101 are performed. For example, the processor 120 may correspond to a component (e.g., a component with a large amount of temperature change) that is relatively greatly affected by the heat generated inside the electronic device 101, and may be included in the first component 330. For example, the processor 120 may be a component that is relatively less affected by the outside temperature. According to an embodiment, the processor 120 may be included in the first component 330 (e.g., a set of components that are greatly affected by the heat generated inside the electronic device 101). For example, the first component 330 may include a component that is arranged adjacent to the processor 120 and is greatly affected by heat generated from the processor 120. The first component 330 may be located at the center of the internal space of the electronic device 101 and may include a component that is relatively less affected by the outside temperature.

According to an embodiment, the battery 189 and the connectivity terminal 178 may be components (e.g., the second component 340) (e.g., components with a small amount of temperature change) that are relatively less affected by the heat generated inside the electronic device 101. For example, the battery 189 and the connectivity terminal 178 may correspond to components that are relatively greatly affected by the outside temperature and may be included in the second component 340. According to an embodiment, the battery 189 and the connectivity terminal 178 may be included in the second component 340 (e.g., a set of components that are greatly affected by the outside temperature). For example, the second component 340 may include a component that is arranged far from the processor 120 and is less affected by the heat generated from the processor 120. The second component 340 may be located in an outer area of the internal space of the electronic device 101 or may be located to be at least partially exposed to the external environment, and may include a component that is relatively greatly affected by the outside temperature when compared to the first component.

According to an embodiment, the electronic device 101 may measure a first temperature of the first component 330 (e.g., the processor 120) and a second temperature of the second component 340 (e.g., the battery 189 and the connectivity terminal 178) according to a predetermined time interval. The electronic device 101 may predict the outside temperature by reflecting the measured first and second temperatures in the prediction model information 312. Referring to FIG. 3, the first component 330 includes the processor 120 and the second component 340 includes the battery 189 and the connectivity terminal 178, but the first component 330 and the second component 340 are not limited to specific components. According to an embodiment, the component whose temperature is measured using at least one of the first temperature sensor 321 and the second temperature sensor 322 may include at least one of the processor 120 (e.g., AP), the battery 189, a charger, the connectivity terminal 178 (e.g., USB terminal), a communication module (e.g., the communication module 190 of FIG. 1 or Wi-Fi module), a camera flash, and/or a modem. According to an embodiment, the components of the electronic device 101 may be classified as the first component 330 and the second component 340 according to a configured condition.

According to an embodiment, the first component 330 and the second component 340 may include a plurality of components whose priorities are determined. According to an embodiment, when an error is identified in measuring the temperature of a 1-1^{st} component (e.g., the first priority) included in the first component 330, the electronic device 101 may measure the temperature of a 1-2^{nd} component (e.g., the second priority) corresponding to the next priority, rather than the 1-1^{st} component. For example, when reflecting the measured temperature of the 1-2^{nd} component in the prediction model information 312 (e.g., prediction model in which prediction parameter data is determined based on Equation 1), the electronic device 101 may input the measured temperature of the 1-2^{nd} component into “T_{AP}” (e.g., first temperature data of the first component 330) of the prediction model. According to an embodiment, the first component 330 and the second component 340 may be replaced with different types of components based on the priorities.

According to an example embodiment, an electronic device (e.g., the electronic device 101 of FIG. 1 and/or FIG. 3) may include: at least one first component (e.g., the first component 330 of FIG. 3) and at least one second component (e.g., the second component 340 of FIG. 3) arranged in an internal space of the electronic device wherein the first component and the second components have temperatures that vary differently depending on the operation of the electronic device; a first temperature sensor (e.g., the first temperature sensor 321 of FIG. 3) configured to measure the temperature of the at least one first component; a second temperature sensor (e.g., the second temperature sensor 322 of FIG. 3) configured to measure the temperature of the at least one second component; a memory (the memory 130 of FIG. 1 and/or FIG. 3); and at least one processor (e.g., the processor 120 of FIG. 1 and/or FIG. 3) operatively connected to the at least one first component, the at least one second component, the first temperature sensor, the second temperature sensor, and the memory. According to an example embodiment, at least one processor may be configured to identify a prediction model related to prediction of the outside temperature stored in the memory. At least one processor may be configured to acquire a first temperature of the at least one first component through the first temperature sensor according to a specified period. At least one processor may be configured to acquire a second temperature of the at least one second component through the second temperature sensor according to a specified period. At least one processor may be configured to predict outside temperatures corresponding to the acquired first temperature and the acquired second temperature based on the identified prediction model.

According to an example embodiment, at least one processor may be configured to execute an application related to prediction of the outside temperature stored in the memory in response to a booting operation of the electronic device. At least one processor may be configured to identify the prediction model based on the executed application.

According to an example embodiment, at least one processor may be configured to identify a difference value between the first temperature and the second temperature. At least one processor may be configured to reflect the identified difference value in the prediction model to predict the outdoor temperature based on the prediction model.

According to an example embodiment, at least one processor may be configured to drive at least one of the at least one first component and the at least one second component based on a configured learning scenario within a test space configured to a third temperature. At least one processor may be configured to identify a first test temperature of the at least one first component and a second test temperature of the at least one second component according to a specified period. At least one processor may be configured to reflect the first test temperature and the second test temperature in a specified mathematical model. At least one processor may be configured to determine prediction parameter data included in the specified mathematical model. At least one processor may be configured to implement the prediction model by substituting the determined prediction parameter data into the specified mathematical model. At least one processor may be configured to store the implemented prediction model in the memory.

According to an example embodiment, the specified mathematical model may be determined based on temperature data related to the at least one first component, temperature data related to the at least one second component, a third temperature configured to correspond to the outside temperature, and the prediction parameter data.

According to an example embodiment, the learning scenario may include a scenario wherein heat is generated inside the electronic device in response to at least one of the at least one first component and the at least one second component being driven.

According to an example embodiment, at least one processor may be configured to identify a situation in which the electronic device is updated in relation to the at least one first component and the at least one second component. At least one processor may be configured to re-determine prediction parameter data based on the configured learning scenario in response to the update of the electronic device.

According to an example embodiment, at least one processor may be configured to identify a first temperature change range in which the first temperature of the at least one first component varies and a second temperature change range in which the second temperature of the at least one second component varies, according to a specified period. When at least one of the first temperature change range and the second temperature change range exceeds a specified threshold value, at least one processor may be configured to at least partially initialize an application related to the prediction of the outside temperature.

According to an example embodiment, the at least one first component 330 may include a 1-1^{st} component and a 1-2^{nd} component having a priority configured to be relatively lower than a priority of the 1-1^{st} component.

According to an example embodiment, at least one processor may be configured to identify a 1-1^{st} temperature change range in which the temperature of the 1-1^{st} component varies and a 1-2^{nd} temperature change range in which the temperature of the 1-2^{nd} component varies, according to a specified period. Based on the 1-1^{st} temperature change range exceeding the specified threshold value, at least one processor may be configured to reflect the 1-2^{nd} component in the prediction model instead of the 1-1^{st} component. At least one processor may be configured to predict the outside temperature corresponding to the temperature of the 1-2^{nd} component based on the prediction model.

According to an example embodiment, at least one processor may be configured to identify the component having a relatively higher priority between the 1-1^{st} component and the 1-2^{nd} component. At least one processor may be configured to predict the outside temperature corresponding to the temperature of the high-priority component based on the prediction model.

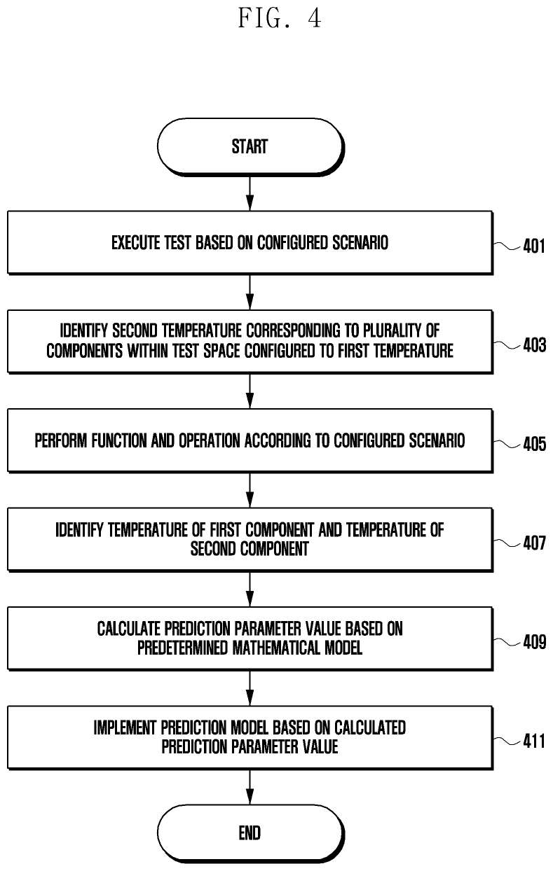

FIG. 4 is a flowchart illustrating an example method of implementing a prediction model according to various embodiments.

In the following example embodiments, respective operations may be performed sequentially, but are not necessarily performed sequentially. For example, the order of each operation may be changed, and at least two operations may be performed in parallel.

The electronic device 101 of FIG. 4 may be at least partially similar to the electronic device 101 of FIGS. 1 and 3 or may further include various embodiments of the electronic device 101. According to an embodiment, the electronic device 101 may have a plurality of components arranged therein, and may use a temperature sensor to measure the temperature corresponding to each of the components. According to an embodiment, at least one temperature sensor may be arranged in response to the at least one component, and may accurately measure the temperature of the at least one component.

FIG. 4 may at least partially include operation 220 of performing data learning in FIG. 2. According to an embodiment, the electronic device 101 may perform data learning 220 based on the flowchart of FIG. 4 and implement a prediction model for predicting the outside temperature.

In operation 401, a processor (e.g., the processor 120 of FIG. 3) of the electronic device 101 may execute a test based on a configured scenario (e.g., learning scenario). For example, the electronic device 101 may be placed in an experimental “space configured at a specific temperature (e.g., about 20 degrees, about 25 degrees, about 30 degrees, about 35 degrees, about 40 degrees, or about 45 degrees) within a predetermined temperature range (e.g., about 20 degrees to about 45 degrees), and perform a test in the experimental space. For example, the processor 120 may execute an application related to prediction of outside temperature and perform the test based on the executed application. According to an embodiment, a configured scenario may include a scenario in which heat is generated inside the electronic device 101 in a situation where a specific function and a specific operation are performed based on at least one component included in the electronic device 101. For example, the scenario may include a first situation in which one of the components operates independently, a second situation in which two of the components operate in combination, and a third situation in which three or more of the components operate in combination. According to an embodiment, the scenario may be configured based on the usage history of a user using the electronic device 101. For example, the processor 120 may identify a function and operation frequently used by the user, and may configure a situation in which the identified function and operation at least partially operates as the scenario.

According to an embodiment, the scenario may include a situation in which heat is generated based on the at least one component while the function or operation is being performed in the electronic device 101. According to an embodiment, the scenario may be configured by a developer and may include a situation in which the at least one component operates independently or in combination.

In operation 403, the processor 120 may identify a second temperature (e.g., a first test temperature of the first component or a second test temperature of the second component) corresponding to a plurality of components (e.g., the first component {e.g., the first component 330 of FIG. 3} and the second component {e.g., the second component 340 of FIG. 3}) within a test space (e.g., experimental space) configured to a first temperature. For example, the electronic device 101 may be placed in the test space configured to the first temperature, and after a predetermined time has elapsed, the second temperature for the first component 330 and the second component 340 may be identified. According to an embodiment, the first component 330 may include components that are relatively greatly affected by the heat generated inside the electronic device 101, and include components arranged adjacent to the component (e.g., the processor 120) that generates heat. The second component 340 may include components that are relatively greatly affected by the outside temperature and include components that are arranged away from the component that generates heat.

In operation 405, the processor 120 may perform functions and operations according to the configured scenario. For example, the processor 120 may at least partially perform functions and operations related to the at least one component for a predetermined time, and power may be consumed as the functions and operations are performed. When power is consumed in the electronic device 101, some of the components (e.g., the processor 120) included in the first component 330 may generate heat, and based on the generated heat, the temperature of the component of the electronic device 101 may be at least partially increased. According to an embodiment, when the temperature of the internal space of the electronic device 101 increases due to the heat generated by the processor 120, the temperature increase (e.g., change range) of the first component 330 may be relatively greater than that of the second component 340. The first component 330 may include components that are relatively greatly affected by heat generation from the processor 120 rather than the second component 340.

In operation 407, the processor 120 may identify the temperature of the first component 330 (e.g., 2-1^{st} temperature) and the temperature of the second component 340 (e.g., 2-2^{nd} temperature). For example, the electronic device 101 may generate heat in the internal space in response to performing the function and operation, and the temperatures of the first component 330 and the second component 340 may at least partially increase due to the generated heat. According to an embodiment, the change range for the temperature (e.g., the 2-1^{st} temperature) of the first component 330 may be greater than the change range for the temperature (e.g., the 2-2^{nd} temperature) of the second component 340. While the function and operation according to the configured scenario are being performed, the processor 120 may periodically identify the temperature of the first component 330 and the temperature of the second component 340 at predetermined time intervals.

In operation 409, the processor 120 may reflect the temperature of the first component 330 and the temperature of the second component 340 based on a predetermined mathematical model (e.g., Equation 1) to calculate prediction parameter data (e.g., α, β, γ, and δ data of Equation 1). For example, the processor 120 may reflect the 2-1^{st} temperature and the 2-2^{nd} temperature measured according to the predetermined time intervals in the predetermined mathematical model, and calculate predicted parameter data. For example, the prediction parameter data may be determined as data with a minimized/reduced error when predicting the outdoor temperature.

In operation 411, the processor 120 may implement the prediction model based on the calculated prediction parameter data. For example, in a predetermined mathematical model (e.g., Equation 1), the prediction model may include a mathematical model in which the calculated prediction parameter data is reflected. The prediction model may refer to a mathematical model in a state in which the prediction parameter data is determined in Equation 1.

According to an embodiment, the processor 120 may identify a first temperature change range according to the temperature change of the first component 330 and a second temperature change range according to the temperature change of the second component 340. The processor 120 may determine whether at least one of the first temperature change range and the second temperature change range exceeds a predetermined threshold value. For example, the threshold value may include a reference value for determining whether the temperature change based on the first component 330 and the second component 340 is included in normal conditions, based on the learning scenario. For example, when the first temperature change range of the first component 330 does not exceed the predetermined threshold value, it may be determined that the temperature measurement of the first component 330 was performed normally. For another example, when the first temperature change range of the first component 330 exceeds the predetermined threshold value, it may be determined that the temperature measurement of the first component 330 was performed abnormally or an error occurred in the temperature measurement. According to an embodiment, the processor 120 may at least partially initialize the application related to the prediction of the outside temperature when the at least one of the first temperature change range and the second temperature change range exceeds the predetermined threshold value.

According to an embodiment, the processor 120 may identify a situation in which the electronic device 101 is updated in relation to the first component 330 and the second component 340, and re-determine the prediction parameter data based on the configured scenario (e.g., learning scenario) in response to the update of the electronic device 101. For example, when the electronic device 101 is updated, the current value consumed by the first component 330 and the second component 340 may be changed, or the amount of temperature change of the first component 330 and the amount of temperature change of the second component 340 may be changed. This may result in lower accuracy for the outside temperature prediction based on previously determined prediction model. According to an embodiment, the processor 120 may re-determine the prediction parameter data in response to the update of the electronic device 101, and re-implement the prediction model based on the re-determined prediction parameter data.

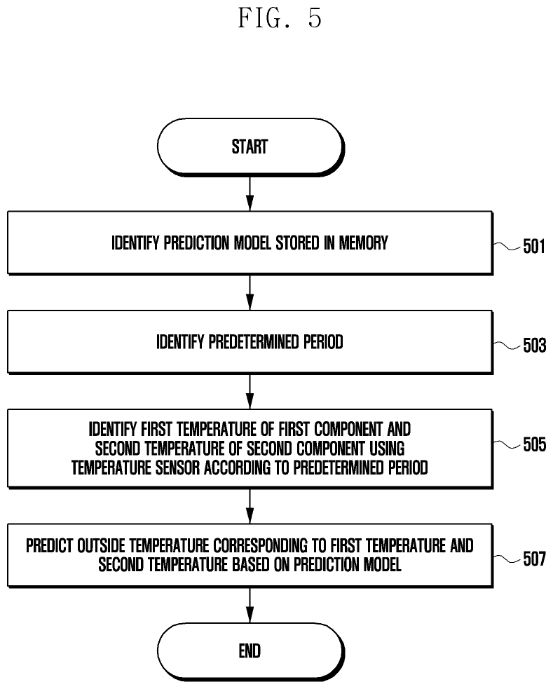

FIG. 5 is a flowchart illustrating an example method of predicting outside temperature according to various embodiments.

In the following embodiments, respective operations may be performed sequentially, but are not necessarily performed sequentially. For example, the order of each operation may be changed, and at least two operations may be performed in parallel.

The electronic device 101 of FIG. 5 may be at least partially similar to the electronic device 101 of FIGS. 1 and 3, or may further include various embodiments of the electronic device 101. According to an embodiment, the electronic device 101 may have a plurality of components arranged therein, and may use a temperature sensor to measure the temperature corresponding to each of the components. According to an embodiment, in response to at least one component (e.g., the first component 330 and the second component 340 of FIG. 3), at least one temperature sensor (e.g., the first temperature sensor 321 and the second temperature sensor 322 of FIG. 3) may be arranged to accurately measure the temperature of the at least one component.

FIG. 5 may at least partially include operation 230 of predicting the outside temperature in real time, which is performed in FIG. 2. According to an embodiment, the electronic device 101 may predict the outside temperature at predetermined time intervals based on the flowchart of FIG. 5.

In operation 501, a processor (e.g., the processor 120 of FIG. 3) of the electronic device 101 may identify a prediction model (e.g., the prediction model information 312 of FIG. 3) stored in a memory (e.g., the memory 130 of FIG. 3). For example, in a state in which the operation (e.g., data learning) of FIG. 4 has been performed, the electronic device 101 may be in a state in which the prediction model implemented by data learning is stored in the memory 130. According to an embodiment, in response to a reboot operation of the electronic device 101, an application for predicting the outside temperature may be initialized. For example, at the time of rebooting, the application for predicting the outside temperature may configure a period (e.g., time interval) in which the outside temperature is predicted, and perform an operation of predicting the outside temperature based on the identified prediction model.

In operation 503, the processor 120 may identify the configured period (e.g., a time interval for predicting the outside temperature). For example, the processor 120 may predict the outside temperature at predetermined time intervals according to the configured period. According to an embodiment, the processor 120 may continuously perform the operation of predicting the outside temperature at every configured period configured by the electronic device 101. According to an embodiment, the period may be set to a plurality of periods. For example, when measuring the first temperature of a first component, a first period may be set, and when measuring the second temperature of a second component, a second period may be set. The processor 120 may measure the first temperature of the first component according to the first period and the second temperature of the second component according to the second period, based on a plurality of temperature sensors (e.g., the first temperature sensor 321 and the second temperature sensor 322).

In operation 505, the processor 120 may use a temperature sensor (e.g., the first temperature sensor 321 and the second temperature sensor 322 in FIG. 3) according to the configured period to identify a first temperature of the first component (e.g., the first component 330 of FIG. 3) and a second temperature of the second component (e.g., the second component 340 of FIG. 3). According to an embodiment, a plurality of temperature sensors (e.g., the first temperature sensor 321 and the second temperature sensor 322) may be implemented and arranged in association with each of the components (e.g., the first component 330 and the second component 340) of the electronic device 101. For example, the first temperature sensor 321 may measure the first temperature of the first component (e.g., the first component 330), and the second temperature sensor 322 may measure the second temperature of the second component (e.g., the second component 340). According to an embodiment, the components of the electronic device 101 may include at least one of the processor 120 (e.g., AP), the battery 189, a charger, the connectivity terminal 178 (e.g., USB terminal), a communication module (e.g., the communication module 190 of FIG. 1 or Wi-Fi module), a camera flash, and/or a modem. According to an embodiment, the components are not limited to the above-described components and may include all components included in the electronic device 101. According to an embodiment, the components of the electronic device 101 may include the first component 330 (e.g., a set of components that are greatly affected by the heat generated inside the electronic device 101) and the second component 340 (e.g., a set of components that are greatly affected by the outside temperature).

According to an embodiment, the electronic device 101 may measure the temperatures of the first component 330 and the second component 340 periodically at the predetermined time intervals. For example, the first component 330 may include a component that is arranged relatively close to the processor 120 and is greatly affected by the heat generated from the processor 120. The second component 340 may include a component that is arranged far from the processor 120 and is less affected by the heat generated from the processor 120. According to an embodiment, the processor 120 may identify the first temperature (e.g., first amount of temperature change) of the first component 330 and the second temperature (e.g., second amount of temperature change) of the second component 340 for a predetermined time, and predict the outside temperature based on the identified amount of temperature change. According to an embodiment, the electronic device 101 may measure the first temperature of the first component 330 based on the first period, and the second temperature of the second component 340 based on the second period different from the first period. For example, the first period and the second period may be set to different periods.

In operation 507, the processor 120 may predict the outside temperature corresponding to the first temperature and the second temperature based on the prediction model (e.g., the prediction model information 312 stored in the memory 130). For example, the prediction model information 312 may include the prediction model implemented in operation 411 of FIG. 4. For example, the processor 120 may substitute the first temperature of the first component 330 and the second temperature of the second component 340 into the prediction model and calculate the outside temperature value. According to an embodiment, the electronic device 101 may identify the first temperature of the first component 330 and the second temperature of the second component 340 at every configured period, and calculate the outside temperature by substituting the identified first temperature and second temperature into the prediction model. For example, the prediction model may include Equation representing a correlation between the temperature values of the components (e.g., the first component 330 and the second component 340) and the value of the outside temperature. The electronic device 101 may predict the outside temperature based on the temperature values for at least two components (e.g., the first component 330 and the second component 340).

According to an embodiment, the first component 330 and the second component 340 are not limited to specific components. For example, the components included in the first component 330 may be prioritized according to the descending order starting from the component that is most affected by the heat generated inside the electronic device 101 (e.g., in the descending order starting from the component having the largest temperature change range by the internal heat generation). When a problem (e.g., a problem in the process of measuring the temperature) occurs in a 1-1^{st} component corresponding to the first priority, the 1-1^{st} component may be replaced with a 1-2^{nd} component corresponding to the second priority. For example, the components included in the second component 340 may be prioritized according to the descending order starting from the component that is most affected by the outside temperature (e.g., in the ascending order starting from the component having the smallest temperature change range by the internal heat generation). When a problem occurs in a 2-1^{st} component corresponding to the first priority, the 2-1^{st} component may be replaced with a 2-2^{nd} component corresponding to the second priority.

According to an embodiment, in measuring the temperature of the component (e.g., the 1-1^{st} component) corresponding to the first priority, when the temperature change range exceeds a predetermined threshold value compared to the previous time, the processor 120 may replace the component with another component (e.g., the 1-2^{nd} component) corresponding to the next priority. For example, in relation to the 1-1^{st} component, the processor 120 may compare previously measured temperature data with currently measured temperature data. When the temperature change range of the temperature data is outside a predetermined reference value (e.g., predetermined threshold value), it may be determined that an error has occurred in relation to the 1-1^{st} component, and the temperature data of the 1-1^{st} component may not be applied to the prediction model. The processor 120 may apply the temperature data of the 1-2^{nd} component corresponding to the next priority of the 1-1^{st} component to the prediction model.

According to an embodiment, in measuring the temperature of the 1-1^{st} component corresponding to the first priority, the processor 120 may measure the temperatures of the 1-2^{nd} component and a 1-3^{rd} component (e.g., other components included in the first component) corresponding to different priorities substantially together. The processor 120 may identify a 1-1^{st} temperature change range at the current period compared to the previous period in relation to the 1-1^{st} component, and identify a 1-2^{nd} temperature change range at the current period compared to the previous period in relation to the 1-2^{nd} component. The processor 120 may compare and analyze the 1-1^{st} temperature change range and the 1-2^{nd} temperature change range, and determine whether the 1-1^{st} temperature change range and the 1-2^{nd} temperature change range meet a normal condition. For example, the normal condition may be configured as a condition (e.g., reference value) indicating a correlation between the temperature of the 1-1^{st} component included in the first component 330 and the temperature of the 1-2^{nd} component included in the first component 330. For example, when a difference value between the temperature of the 1-1^{st} component and the temperature of the 1-2^{nd} component deviates from the normal condition (e.g., reference value), the processor 120 may determine that an error has occurred in the temperature data for at least one of the 1-1^{st} component and the 1-2^{nd} component. According to an embodiment, when an error is identified in relation to the temperature measurement of the 1-1^{st} component, the processor 120 may not apply the temperature data of the 1-1^{st} component to the prediction model. The processor 120 may replace the 1-1^{st} component in which the error was identified with the 1-2^{nd} component. The processor 120 may apply the temperature data of the 1-2^{nd} component to the prediction model.

According to an embodiment, the electronic device 101 may predict the outside temperature and perform various functions and operations based on the predicted outside temperature. For example, the electronic device 101 may utilize the predicted outside temperature based on a thermometer application that provides the outside temperature of the current location. For example, the electronic device 101 may utilize the predicted outside temperature based on an application related to heat generation control and an application related to data protection.

A method of predicting an outside temperature by an electronic device (e.g., the electronic device 101 of FIG. 3) according to an example embodiment may include: identifying a prediction model related to prediction of the outside temperature stored in a memory (e.g., the memory 130 of FIG. 3), acquiring a first temperature of at least one first component (e.g., the first component 330 of FIG. 3) through a first temperature sensor (e.g., the first temperature sensor 321 of FIG. 3) according to a specified period, acquiring a second temperature of at least one second component (e.g., the second component 340 of FIG. 3) through a second temperature sensor (e.g., the second temperature sensor 322 of FIG. 3) according to a specified period, and predicting the outside temperature corresponding to the acquired first and second temperatures based on the identified prediction model. According to an example embodiment, the at least one first component may include a component whose temperatures varies as the electronic device is driven, and the at least one second component may include a component whose temperature relatively slightly varies compared to the at least one first component.

The identifying of the prediction model according to an example embodiment may include: executing an application related to prediction of the outside temperature stored in the memory in response to a booting operation of the electronic device, and identifying the prediction model based on the executed application.

The predicting of the outside temperature according to an example embodiment may include: identifying a difference value between the first temperature and the second temperature, and predicting the outside temperature based on the prediction model by reflecting the difference value in the prediction model.

The method according to an example embodiment may further include: driving at least one of the at least one first component and the at least one second component based on a configured learning scenario within a test space configured to a third temperature, identifying a first test temperature of the at least one first component and a second test temperature of the at least one second component according to a specified period, reflecting the first test temperature and the second test temperature in a specified mathematical model, determining prediction parameter data included in the specified mathematical model, implementing the prediction model by substituting the determined prediction parameter data into the specified mathematical model, and storing the implemented prediction model in the memory (e.g., the memory 130 of FIG. 3).

According to an example embodiment, the specified mathematical model may be determined based on temperature data related to the at least one first component, temperature data related to the at least one second component, a third temperature configured to correspond to the outside temperature, and the prediction parameter data.

According to an example embodiment, the learning scenario may include a scenario in which heat is generated inside the electronic device in response to a situation in which at least one of the at least one first component and the at least one second component is driven.

The method according to an example embodiment may further include: identifying a situation in which the electronic device is updated in relation to the at least one first component and the at least one second component, and re-determining the prediction parameter data based on the configured learning scenario.

The method according to an example embodiment may further include: identifying a first temperature change range in which the first temperature of the at least one first component varies and a second temperature change range in which the second temperature of the at least one second component varies, and at least partially initializing the application related to the prediction of the outside temperature based on at least one of the first temperature change range and the second temperature change range exceeding a threshold value.

According to an example embodiment, the at least one first component may include a 1-1^{st} component and a 1-2^{nd} component having a priority configured to be relatively lower than that of the 1-1^{st} component. The method according to an example embodiment may further include: identifying a 1-1^{st} temperature change range in which the temperature of the 1-1^{st} component varies and a 1-2^{nd} temperature change range in which the temperature of the 1-2^{nd} component varies, reflecting the 1-2^{nd} component in the prediction model instead of the 1-1^{st} component based on the 1-1^{st} temperature change range exceeding a threshold value, and predicting the outside temperature corresponding to the temperature of the 1-2^{nd} component based on the prediction model.

The method according to an example embodiment may further include: identifying a component with a relatively higher priority between the 1-1^{st} component and the 1-2^{nd} component, and predicting the outside temperature corresponding to the temperature of the component with the higher priority based on the prediction model.

The electronic device according to various embodiments may be one of various types of electronic devices. The electronic devices may include, for example, a portable communication device (e.g., a smartphone), a computer device, a portable multimedia device, a portable medical device, a camera, a wearable device, a home appliance, or the like. According to an embodiment of the disclosure, the electronic devices are not limited to those described above.

It should be appreciated that various embodiments of the present disclosure and the terms used therein are not intended to limit the technological features set forth herein to particular embodiments and include various changes, equivalents, or replacements for a corresponding embodiment. It is intended that features described with respect to separate embodiments, or features recited in separate claims, may be combined unless such a combination is explicitly specified as being excluded or such features are incompatible. With regard to the description of the drawings, similar reference numerals may be used to refer to similar or related elements. It is to be understood that a singular form of a noun corresponding to an item may include one or more of the things, unless the relevant context clearly indicates otherwise. As used herein, each of such phrases as “A or B,” “at least one of A and B,” “at least one of A or B,” “A, B, or C,” “at least one of A, B, and C,” and “at least one of A, B, or C,” may include any one of, or all possible combinations of the items enumerated together in a corresponding one of the phrases. As used herein, such terms as “1^{st}” and “2^{nd},” or “first” and “second” may be used to simply distinguish a corresponding component from another, and does not limit the components in other aspect (e.g., importance or order). It is to be understood that if an element (e.g., a first element) is referred to, with or without the term “operatively” or “communicatively”, as “coupled with,” “coupled to,” “connected with,” or “connected to” another element (e.g., a second element), the element may be coupled with the other element directly (e.g., wiredly), wirelessly, or via a third element.

As used in connection with various embodiments of the disclosure, the term “module” may include a unit implemented in hardware, software, or firmware, or any combination thereof, and may interchangeably be used with other terms, for example, “logic,” “logic block,” “part,” or “circuitry”. A module may be a single integral component, or a minimum unit or part thereof, adapted to perform one or more functions. For example, according to an embodiment, the module may be implemented in a form of an application-specific integrated circuit (ASIC).

Various embodiments as set forth herein may be implemented as software (e.g., the program 140) including one or more instructions that are stored in a storage medium (e.g., internal memory 136 or external memory 138) that is readable by a machine (e.g., the electronic device 101). For example, a processor (e.g., the processor 120) of the machine (e.g., the electronic device 101) may invoke at least one of the one or more instructions stored in the storage medium, and execute it, with or without using one or more other components under the control of the processor. This allows the machine to be operated to perform at least one function according to the at least one instruction invoked. The one or more instructions may include a code generated by a compiler or a code executable by an interpreter. The machine-readable storage medium may be provided in the form of a non-transitory storage medium. Wherein, the “non-transitory” storage medium is a tangible device, and may not include a signal (e.g., an electromagnetic wave), but this term does not differentiate between where data is semi-permanently stored in the storage medium and where the data is temporarily stored in the storage medium.

According to an embodiment, a method according to various embodiments of the disclosure may be included and provided in a computer program product. The computer program product may be traded as a product between a seller and a buyer. The computer program product may be distributed in the form of a machine-readable storage medium (e.g., compact disc read only memory (CD-ROM)), or be distributed (e.g., downloaded or uploaded) online via an application store (e.g., PlayStore™), or between two user devices (e.g., smart phones) directly. If distributed online, at least part of the computer program product may be temporarily generated or at least temporarily stored in the machine-readable storage medium, such as memory of the manufacturer's server, a server of the application store, or a relay server.

According to various embodiments, each component (e.g., a module or a program) of the above-described components may include a single entity or multiple entities, and some of the multiple entities may be separately disposed in different components. According to various embodiments, one or more of the above-described components may be omitted, or one or more other components may be added. Alternatively or additionally, a plurality of components (e.g., modules or programs) may be integrated into a single component. In such a case, according to various embodiments, the integrated component may still perform one or more functions of each of the plurality of components in the same or similar manner as they are performed by a corresponding one of the plurality of components before the integration. According to various embodiments, operations performed by the module, the program, or another component may be carried out sequentially, in parallel, repeatedly, or heuristically, or one or more of the operations may be executed in a different order or omitted, or one or more other operations may be added.

While the disclosure has been illustrated and described with reference to various example embodiments, it will be understood that the various example embodiments are intended to be illustrative, not limiting. It will be further understood by those skilled in the art that various changes in form and detail may be made without departing from the true spirit and full scope of the disclosure, including the appended claims and their equivalents. It will also be understood that any of the embodiment(s) described herein may be used in conjunction with any other embodiment(s) described herein.

What is claimed is:

1. An electronic device comprising:
at least one first component and at least one second component arranged in an internal space of the electronic device wherein temperatures of the first component and the second component vary differently based on the operation of the electronic device;
a first temperature sensor configured to measure a temperature of the at least one first component;
a second temperature sensor configured to measure a temperature of the at least one second component;
memory; and
at least one processor, comprising processing circuitry, operatively connected to the at least one first component, the at least one second component, the first temperature sensor, the second temperature sensor, and the memory,
wherein at least one processor is configured to:
identify a prediction model related to prediction of the outside temperature stored in the memory;
acquire a first temperature of the at least one first component through the first temperature sensor according to a specified period;
acquire a second temperature of the at least one second component through the second temperature sensor according to a specified period; and
predict the outside temperature corresponding to the acquired first temperature and the acquired second temperature based on the identified prediction model.

2. The electronic device of claim 1, wherein at least one processor is configured to:
execute an application related to prediction of the outside temperature stored in the memory in response to a booting operation of the electronic device; and
identify the prediction model based on the executed application.

3. The electronic device of claim 1, wherein at least one processor is configured to:
identify a difference value between the first temperature and the second temperature; and
reflect the identified difference value in the prediction model to predict the outdoor temperature based on the prediction model.

4. The electronic device of claim 1, wherein at least one processor is configured to:
drive at least one of the at least one first component and the at least one second component based on a configured learning scenario within a test space configured to a third temperature;
identify a first test temperature of the at least one first component and a second test temperature of the at least one second component according to a specified period;
reflect the first test temperature and the second test temperature in a specified mathematical model;
determine prediction parameter data included in the specified mathematical model;
implement the prediction model by substituting the determined prediction parameter data into the specified mathematical model; and
store the implemented prediction model in the memory.

5. The electronic device of claim 1,
wherein the determined mathematical model is determined based on temperature data related to the at least one first component, temperature data related to the at least one second component, a third temperature configured to correspond to the outside temperature, and the prediction parameter data, and
wherein the learning scenario comprises a scenario where heat is generated inside the electronic device in response to at least one of the at least one first component and the at least one second component are driven.

6. The electronic device of claim 1, wherein at least one processor is configured to:
identify that the electronic device is updated in relation to the at least one first component and the at least one second component; and
re-determine prediction parameter data based on the configured learning scenario in response to the update of the electronic device.

7. The electronic device of claim 1, wherein at least one processor is configured to:
identify a first temperature change range in which the first temperature of the at least one first component varies and a second temperature change range in which the second temperature of the at least one second component varies, according to a specified period; and
at least partially initialize an application related to the prediction of the outside temperature based on at least one of the first temperature change range and the second temperature change range exceeding a specified threshold value.

8. The electronic device of claim 1, wherein the at least one first component comprises a 1-1^{st} component and a 1-2^{nd} component having priority configured to be relatively lower than a priority of the 1-1^{st} component, and
wherein at least one processor is configured to:
identify a 1-1^{st} temperature change range in which the temperature of the 1-1^{st} component varies and a 1-2^{nd} temperature change range in which the temperature of the 1-2^{nd} component varies, according to a specified period;
reflect the 1-2^{nd} component in the prediction model instead of the 1-1^{st} component based on the 1-1^{st} temperature change range exceeding the specified threshold value; and
predict the outside temperature corresponding to the temperature of the 1-2^{nd} component based on the prediction model.

9. The electronic device of claim 1, wherein at least one processor is configured to:
identify a component having a relatively higher priority between the 1-1^{st} component and the 1-2^{nd} component; and
predict the outside temperature corresponding to the temperature of the high-priority component based on the prediction model.

10. A method of predicting an outside temperature by an electronic device, the method comprising:
identifying a prediction model related to prediction of the outside temperature stored in a memory;
acquiring a first temperature of at least one first component through a first temperature sensor according to a specified period;
acquiring a second temperature of at least one second component through a second temperature sensor according to a specified period; and
predicting the outside temperature corresponding to the acquired first and second temperatures based on the identified prediction model,
wherein the temperatures of the at least one first component and the at least one second component vary differently based on the operation of the electronic device.

11. The method of claim 10, wherein the identifying of the prediction model comprises:
executing an application related to prediction of the outside temperature stored in the memory in response to a booting operation of the electronic device; and
identifying the prediction model based on the executed application.

12. The method of claim 10, wherein the predicting of the outside temperature comprises:
identifying a difference value between the first temperature and the second temperature; and
predicting the outside temperature based on the prediction model by reflecting a conformed difference value in the prediction model.

13. The method of claim 10, further comprising:
driving at least one of the at least one first component and the at least one second component based on a configured learning scenario within a test space configured to a third temperature;
identifying a first test temperature of the at least one first component and a second test temperature of the at least one second component according to a specified period;
reflecting the first test temperature and the second test temperature in a specified mathematical model;
determining prediction parameter data included in the specified mathematical model;
implementing the prediction model by substituting the determined prediction parameter data into the specified mathematical model; and
storing the implemented prediction model in the memory.

14. The method of claim 10, wherein the specified mathematical model is determined based on temperature data related to the at least one first component, temperature data related to the at least one second component, a third temperature configured to correspond to the outside temperature, and the prediction parameter data.

15. The method of claim 10, wherein the learning scenario comprises a scenario in which heat is generated inside the electronic device in response to at least one of the at least one first component and the at least one second component is driven.

16. The method of claim 10, further comprising:
identifying that the electronic device is updated in relation to the at least one first component and the at least one second component; and
re-determining the prediction parameter data based on the configured learning scenario in response to the update of the electronic device.

17. The method of claim 10, further comprising:
identifying a first temperature change range in which the first temperature of the at least one first component varies and a second temperature change range in which the second temperature of the at least one second component varies; and
at least partially initializing the application related to the prediction of the outside temperature based on at least one of the first temperature change range and the second temperature change range exceeding a threshold value.

18. The method of claim 10, wherein the at least one first component comprises a 1-1^{st} component and a 1-2^{nd} component having a priority relatively lower than a priority of the 1-1^{st} component, the method further comprising:
identifying a 1-1^{st} temperature change range in which the temperature of the 1-1^{st} component varies and a 1-2^{nd} temperature change range in which the temperature of the 1-2^{nd} component varies;
reflecting the 1-2^{nd} component in the prediction model instead of the 1-1^{st} component based on the 1-1^{st} temperature change range exceeding a threshold value; and
predicting the outside temperature corresponding to the temperature of the 1-2^{nd} component based on the prediction model.

19. The method of claim 10, further comprising:
identifying a component with a relatively higher priority between the 1-1^{st} component and the 1-2^{nd} component; and
predicting the outside temperature corresponding to the temperature of the component with the higher priority based on the prediction model.

20. One or more non-transitory computer-readable storage media storing computer-executable instructions that, when executed by at least one processor of an electronic device, cause the electronic device to perform operations, the operations comprising:
identifying a prediction model related to prediction of the outside temperature stored in a memory;
acquiring a first temperature of at least one first component through a first temperature sensor according to a specified period;
acquiring a second temperature of at least one second component through a second temperature sensor according to a specified period; and
predicting the outside temperature corresponding to the acquired first and second temperatures based on the identified prediction model,
wherein the temperatures of the at least one first component and the at least one second component vary differently based on the operation of the electronic device.
